(19) United States
(12) Patent Application Publication
(10) Pub. No.: US 2024/0302205 A1
(43) Pub. Date: Sep. 12, 2024

(54) COMPACT VIBRATION SENSOR WITH PIEZO ELECTRIC READ-OUT

(71) Applicant: Sonion Nederland B.V., Hoofddorp (NL)

(72) Inventor: Adriana Maria LAFORT, Hoofddorp (NL)

(73) Assignee: Sonion Nederland B.V., Hoofddorp (NL)

(21) Appl. No.: 18/572,033

(22) PCT Filed: Jun. 14, 2022
(86) PCT No.: PCT/EP2022/066187

§ 371 Date: Dec. 19, 2023

(30) Foreign Application Priority Data
Jun. 21, 2021 (DK) PA202170316

(51) Int. Cl. G01H 11/08; H04R 1/04; H10N 30/30

(52) U.S. Cl. CPC G01H 11/08; H04R 1/04; H10N 30/302; H10N 30/306; H04R 2201/003; H04R 2460/13

(57) ABSTRACT

The present invention relates to a vibration sensor comprising a carrier substrate comprising a first surface and a second surface, a suspension member and a moveable mass secured thereto, wherein the moveable mass and/or at least part of the suspension member is/are adapted to vibrate when the vibration sensor is exposed to external vibrations, a read-out arrangement for detecting vibrations of the moveable mass and/or at least part of the suspension member, and a signal processor for at least processing an electric signal from the read-out arrangement, wherein the read-out arrangement comprises one or more piezo electric layers and one or more electrodes arranged on the respective piezo electric layers. The suspension member forms a cantilever beam comprising a static end, a moveable end and a virtual hinge line arranged in between, wherein at least part of the moveable mass is secured to the cantilever beam between the virtual hinge line and the moveable end, and wherein the one or more piezo electric layers are secured to the cantilever beam in a manner so that the one or more piezo electric layers intersect the virtual hinge line. The present invention further relates to a hearing device comprising a vibration sensor and use of the vibration sensor for voice recognition in a hearing device.

### FIELD OF THE INVENTION

The present invention relates to a vibration sensor comprising a carrier substrate comprising a first surface and a second surface, a suspension member and a moveable mass secured thereto, wherein the moveable mass and/or at least part of the suspension member is/are adapted to vibrate when the vibration sensor is exposed to external vibrations, a read-out arrangement for detecting vibrations of the moveable mass and/or at least part of the suspension member, and a signal processor for at least processing an electric signal from the read-out arrangement, wherein the read-out arrangement comprises one or more piezo electric layers and one or more electrodes arranged on the respective piezo electric layers. According to the present invention the shape and the dimensions of a moveable mass, and the layout of the piezo electric read-out arrangement are mutually optimised in order not to increase the overall dimensions of the vibration sensor.

### BACKGROUND OF THE INVENTION

Vibration sensors to be used in modern hearing devices need to be very compact as the available space in modern hearing devices is very limited. Thus, the designers of vibration sensors are constantly faced with demanding challenges with respect to the dimensions and the performance of such vibration sensors. An example of the prior art sensor may for example be found in US 2008/072677 A1 which discloses an accelerometer comprising a piezo electric signal crystal in the form of a cantilever beam having a free portion. A metal shim is secured to the piezo electric signal crystal. The cantilever beam is adapted to bend when exposed to external accelerations. The accelerometer suggested in US 2008/072677 A1 is disadvantageous in that it does not involve moveable masses-the omitted moveable masses reduce the sensitivity of the accelerometer suggested in US 2008/072677 A1. Moreover, the accelerometer suggested in US 2008/072677 A1 relies on a piezo electric signal crystal formed as a cantilever beam-this approach is disadvantageous seen from a manufacturing point of view.

It may be seen as an object of the embodiments of the present invention to optimise the shape and the dimensions of a moveable mass without increasing the overall dimensions of a vibration sensor.

It may be seen as a further object of embodiments of the present invention to optimise the layout of the piezo electric read-out arrangement without increasing the overall dimensions of a vibration sensor.

### DESCRIPTION OF THE INVENTION

The above-mentioned objects are complied with by providing, in a first aspect, a vibration sensor comprising
a) a carrier substrate comprising a first surface and a second surface,
b) a suspension member and a moveable mass secured thereto, wherein the moveable mass and/or at least part of the suspension member is/are adapted to vibrate when the vibration sensor is exposed to external vibrations,
c) a read-out arrangement for detecting vibrations of the moveable mass and/or at least part of the suspension member, and
d) a signal processor for at least processing an electric signal from the read-out arrangement,
   wherein the read-out arrangement comprises one or more piezo electric layers and one or more electrodes arranged on the respective piezo electric layers, and wherein the suspension member forms a cantilever beam comprising a static end, a moveable end and a virtual hinge line arranged in between, and wherein at least part of the moveable mass is secured to the cantilever beam between the virtual hinge line and the moveable end, and wherein the one or more piezo electric layers are secured to the cantilever beam in a manner so that the one or more piezo electric layers intersect the virtual hinge line.

The vibration sensor of the present invention is advantageous with respect to the mutual arrangement of the moveable mass and the one or more piezo electric layers in that 1) at least part of the moveable mass is secured to the cantilever beam between the virtual hinge line and the moveable end, and that 2) the one or more piezo electric layers are secured to the cantilever beam in a manner so that the one or more piezo electric layers intersect the virtual hinge line. Thus, the moveable mass is preferably secured to the cantilever beam (between the virtual hinge line and the moveable end) in a region where the cantilever beam is not intended to bend when the vibration sensor is exposed to external vibrations. Similarly, the one or more piezo electric layers are preferably secured to the cantilever beam at least in a region where the cantilever beam is intended to bend when the vibration sensor is exposed to external vibrations.

Moreover, the vibration sensor of the present invention is advantageous in that the shape and the dimensions of the moveable mass as well as the layout of the piezo electric read-out arrangement are optimised in order not to increase the overall dimensions of the vibration sensor. Finally, the vibration sensor of the present invention is advantageous in that it incorporates only low-cost technologies.

In the present context, and as it will be discussed in further detail below, the term “virtual hinge line” defines a line between the static end and the moveable end of the cantilever beam where the cantilever beam effectively bends when the moveable mass is displaced due to external vibrations.

The vibration sensor of the present invention is advantageous in that it provides a low noise level and has a relatively small overall size. The low noise level is provided due to an incorporation of a large moveable mass (>1 mg).

The vibration sensor of the present invention applies a piezo electric detection principle for detecting the displacements of the moveable mass when the vibration sensor is exposed to external vibrations. As it will be discussed in further detail below, one or more piezo electric layers with one or more electrodes arranged thereon is/are arranged on the suspension member. A displacement of the moveable mass bends the suspension member whereby the one or more piezo electric layers is/are stretched or compressed in the lateral direction. Whether the one or more piezo electric layers is/are stretched or compressed depends on the direction of the displacement of the moveable mass when the suspension member is bent.

The change in the lateral strain of the one or more piezo electric layers will cause a change in electrical field strength across each of the one or more piezo electric layers, i.e. across the thickness of the one or more piezo electric layers. The change in field strength across the one or more piezo electric layers will cause a change in voltage generated between two electrodes arranged on opposite sides of each of the one or more piezo electric layers.

Preferably, the thickness and width of the one or more piezo electric layers are adapted to the thickness and width of the suspension member so that strain induced in the one or more piezo electric layers has uniformly the same sign when they are stretched or compressed.

Preferably, the material of the suspension member is selected so that the one or more piezo elastic layers can be arranged directly on the suspension member. Moreover, the material of the suspension member is preferably electrically conducting so that the suspension member can be used as one of the electrodes sandwiching the one or more piezo electric layers.

Preferably, the one or more electrodes arranged on the respective piezo electric layers are dimensioned so that they do no influence the stiffness of the suspension member.

With respect to the geometry of the suspension member, the geometry is chosen so that the required resonance frequency is obtained with the required moveable mass, and so that no plastic deformation can occur if the vibration sensor is exposed to extreme mechanical shocks, e.g. when being dropped. With respect to the resonance frequency the length of the suspension member is preferably adjusted to the thickness and width of the suspension member in order to meet the required stiffness. With respect to plastic deformation, the thickness and width of the suspension member should be as small as possible, such as a thickness in the range of 10-50 μm and a width in the range of 200-500 μm.

The vibration sensor of the present invention is preferably suitable for being incorporated into hearing devices, such as a hearing aid, a hearable, a headset, an earbud, personal audio and personal communication devices or a similar device. The roles of the vibration sensor may be numerous, such as detecting voice induced vibrations via bone conduction in the skull. Detection of such voice induced vibrations in the skull is preferably used in relation to voice recognition where the user's own voice is separated or recognised in an otherwise acoustically noisy environment.

In one embodiment of the vibration sensor, at least part of the moveable mass preferably extends from the moveable end to the virtual hinge line of the cantilever beam. The moveable mass comprises a first part preferably being substantially aligned with the moveable end of the cantilever beam, and a second part preferably being substantially aligned with the virtual hinge line of the cantilever beam. Thus, the moveable mass extends from the moveable end of the cantilever beam to the virtual hinge line of the cantilever beam. Optionally, the moveable mass may extend beyond the moveable end of the cantilever beam, or the moveable mass may, for other reasons, not extend entirely from the moveable end of the cantilever beam to the virtual hinge line of the cantilever beam.

As already mentioned, the mass of the moveable mass needs to be relatively high, such as higher than 1 mg. As the moveable mass typically has a thickness in the range of 100-200 μm, the surface areas of the moveable mass can be up to 2.5 mm². In terms of manufacturing the moveable mass may be made of a variety of materials including steel, tantalum or tungsten.

Preferably, the width of the second part of the moveable mass is smaller than the width of the first part of the moveable mass. It is advantageous in that the smaller width of the second part of the moveable mass facilitates that one or more piezo electric layers may be arranged next to the second part of the moveable mass. Preferably, at least part of the second part of the moveable mass is arranged between two piezo electric layers secured to the cantilever beam in a manner so that the two piezo electric layers intersect the virtual hinge line. Arranging the two piezo electric layers so that they intersect the virtual hinge line is advantageous in that the sensitivity of the read-out arrangement of the vibration sensor then becomes high since the cantilever beam effectively bends at the virtual hinge line. Moreover, as the two piezo electric layers and the second part of the moveable mass spatially overlap, the overall size of the vibration sensor can be kept at a minimum thus providing a compact vibration sensor.

In another embodiment the first part of the moveable mass is preferably secured to the cantilever beam, while the second part of the moveable mass forms an overhang above the cantilever beam so that an air gap is formed between the second part of the moveable mass and the cantilever beam. The first part of the moveable mass is preferably secured to the cantilever beam between the moveable end and the virtual hinge line of the cantilever beam. Thus, the area where the moveable mass is secured to the cantilever beam does not intersect the virtual hinge line. In this embodiment the one or more piezo electric layers are preferably secured to the cantilever beam in a manner so that the one or more piezo electric layers extend into the air gap between the second part of the moveable mass and the cantilever beam, and intersect the virtual hinge line. Arranging the piezo electric layer so that it intersects the virtual hinge line is advantageous in that the sensitivity of the read-out arrangement of the vibration sensor then becomes high since the cantilever beam effectively bends at the virtual hinge line. Moreover, as the piezo electric layer and the second part of the moveable mass spatially overlap the overall size of the vibration sensor can be kept at a minimum thus providing a compact vibration sensor.

Preferably, the moveable mass and the signal processor are arranged on opposite sides of the carrier substrate. In the present context the term opposite means that the moveable mass is arranged on one side of the carrier substrate, whereas the signal processor is arranged on another side of the carrier substrate. With this arrangement the carrier substrate becomes arranged between the moveable mass and the signal processor. This is advantageous in that it reduces the overall size of the vibration sensor as projections of the moveable mass and the signal processor overlap spatially in a plane defined by the carrier substrate.

The plane defined by the carrier may coincide with the first surface or the second surface of the carrier substrate, or it may be a virtual plane being parallel with the first surface or the second surface of the carrier substrate. In the present context spatially overlapping of the moveable mass and the signal processor occur when a projected area of the moveable mass overlaps with a projected area of the signal processor in the plane defined by the carrier substrate.

Preferably, the carrier substrate comprises a first printed circuit board (PCB) comprising first and second opposing surfaces. Thus, the carrier substrate is preferably implemented as a PCB comprising the first and second surfaces which may be considered upper and lower surfaces, respectively. Implementing the carrier substrate as a PCB is advantageous in that electronics, such as electrodes, the signal processor etc., can be connected directly to the PCB. In this respect, the signal processor is preferably secured to the second surface of the first PCB.

Preferably the vibration sensor further comprises a spacer, secured to the second surface of the first PCB, wherein the spacer comprises one or more vias electrically connected to the second surface of the first PCB. Preferably the vibration sensor further comprises a second PCB comprising first and second opposing surfaces, wherein the one or more vias of the spacer are electrically connected to the first surface of the second PCB, and wherein one or more contact pads are provided on the second surface of the second PCB for connecting the vibration sensor to external electronic devices. Thus, the incorporation of the spacer, the one or more vias and the second PCB is advantageous in that these elements facilitate that the internal electrical connections of the vibration sensor can be easily implemented. In the present context external electronic devices may include power supplies and additional signal processors, such as amplifiers, filters etc.

In a second aspect the present invention relates to a hearing device comprising a vibration sensor according to the first aspect, wherein the hearing device comprises a hearing aid, a hearable, a headset, an earbud or a similar device.

In a third aspect the present invention relates to a use of a vibration sensor according to the first aspect, wherein the vibration sensor is used for detecting voice induced vibrations in the skull of the user of the hearing device, and wherein the detected voice induced vibrations are used for voice recognition of the user's own voice.

In general, the various aspects of the present invention may be combined and coupled in any way possible within the scope of the invention. These and other aspects, features and/or advantages of the present invention will be apparent from and elucidated with reference to the embodiments described hereinafter.

### BRIEF DESCRIPTION OF THE DRAWINGS

The present invention will now be described with reference to the accompanying drawings where

FIG. 1 shows a cross-sectional view of a first embodiment of the present invention,

FIG. 2 shows an illustration of the virtual hinge line,

FIG. 3 shows a top view of the first embodiment of the present invention,

FIG. 4 shows a cross-sectional view of a second embodiment of the present invention, and

FIG. 5 shows a top view of the second embodiment of the present invention.

### DETAILED DESCRIPTION OF THE INVENTION

In general the present invention relates to a vibration sensor suitable for being incorporated into hearing devices. The vibration sensor is advantageous due to its mutual arrangement of a moveable mass and one or more piezo electric layers of a read-out arrangement for detecting displacements of the moveable mass when the vibration sensor is exposed to external vibrations. Moreover, the vibration sensor of the present invention is advantageous in that the shape and the dimensions of a moveable mass as well as the layout of the piezo electric read-out arrangement are optimised in order not to increase the overall dimensions of the vibration sensor.

In order to detect voice induced vibration signals via bone conduction, the bandwidth of the vibration sensor is typically larger than 6 kHz. In addition to this, the resonance frequency of the vibration sensor is typically close to the upper limit of bandwidth, e.g. above 4 kHz, and the resonance peak is typically less than 10 dB compared to the sensitivity at 1 KHz. With this approach Q will typically be smaller than 3. Moreover, the input referred noise, or equivalent input noise of the vibration sensor should be low, i.e. <−98 dB re. 1 g in ⅓^{rd} octave band at the resonance frequency. In order to meet these requirements the mass of the moveable mass needs to be relatively high, such as higher than 1 mg. As the moveable mass typically has a thickness in the range of 100-200 μm, the large surface areas of the moveable mass can be up to 2.5 mm². In terms of manufacturing, the moveable mass may be made of a variety of materials including steel, tantalum or tungsten.

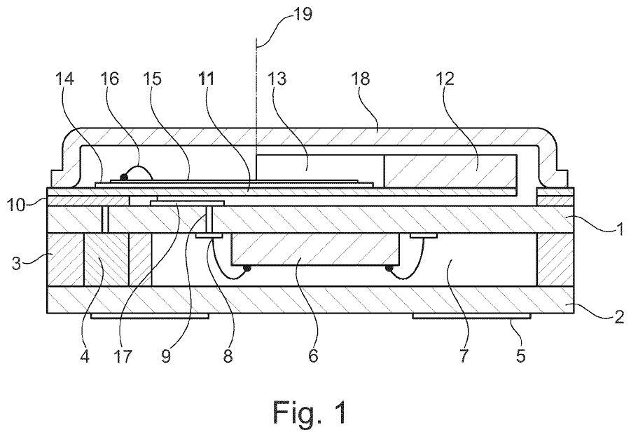

Referring now to FIG. 1, a cross-sectional view of an embodiment of the present invention is depicted. As seen in FIG. 1, a moveable mass comprising two parts 12, 13—a first part 12 and a second part 13 where only the first part 12 of the moveable mass is secured to a suspension member 11. The suspension member 11 has the form of a cantilever beam having 1) a static end secured to a spacer 10, and 2) a moveable end substantially aligned with the moveable mass part 12. The moveable mass 12, 13 and at least the moveable end of the suspension member 11 is adapted to displace when the vibration sensor is exposed to external vibrations. A housing 18 protects the cantilever beam 11 and the moveable mass 12, 13 secured thereto.

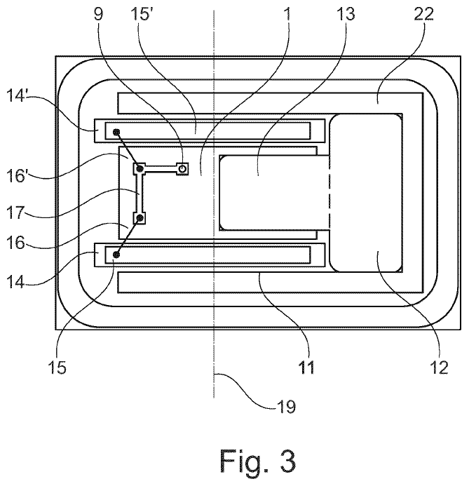

As already mentioned, the vibration sensor applies a piezo electric detection principle for detecting the displacements of the moveable mass 12, 13 when the vibration sensor is exposed to external vibrations. In the embodiment shown in FIG. 1, see also top view in FIG. 3, two piezo electric layers 14, 14′ with respective electrodes 15, 15′ arranged thereon are arranged on the cantilever beam 11 so that they intersect the virtual hinge line 19. A displacement (up or down) of the moveable mass 12, 13 bends the cantilever beam 11 at the virtual hinge line 19 whereby the two piezo electric layers 14, 14′ are stretched or compressed in the lateral direction. The change in the lateral strain of the two piezo electric layers 14, 14′ will induce a change in the electrical field strength across each of the piezo electric layers 14, 14′, i.e. across the thickness of the two piezo electric layers 14, 14′. The change in the field strength across the piezo electric layers 14, 14′ will provide a change in the voltage generated between two electrodes arranged on opposite sides of each of the two piezo electric layers 14, 14′. In the embodiment shown in FIG. 1, the lower electrodes (grounded) of the two piezo electric layers 14, 14′ are formed by the cantilever beam 11, whereas separate electrodes 15, 15′ are formed on each of the two piezo electric layers 14, 14′. These separate electrodes 15, 15′ are electrically connected to the signal processor 6 via the wire bonding 16, 16′, the electrode 17 on the first PCB 1, the via 9 through the first PCB 1 and the wire bonding 8 to the signal processor 6. Thus, the detected voltage change across the two piezo electric layers 14, 14′ is processed by the signal processor 6 that may be operating in the analog or digital domain applying any digital coding scheme.

The vibration sensor depicted in FIG. 1 further comprises a second PCB 2 comprising first and second opposing surfaces, wherein one or more contact pads 5 are provided on the second surface of the second PCB 2. The one or more contact pads 5 facilitate easy connection of the vibration sensor to external electronic devices, such as external signal processors, filters, amplifiers etc. in for example hearing devices. Moreover, a spacer 3 is provided between the first PCB 1 and the second PCB 2 so that a cavity 7 is formed by the first PCB 1 and the second PCB 2 and the spacer 3. The spacer 3 comprises one or more vias 4 for electrically interconnecting the first PCB 1 and the second PCB 2.

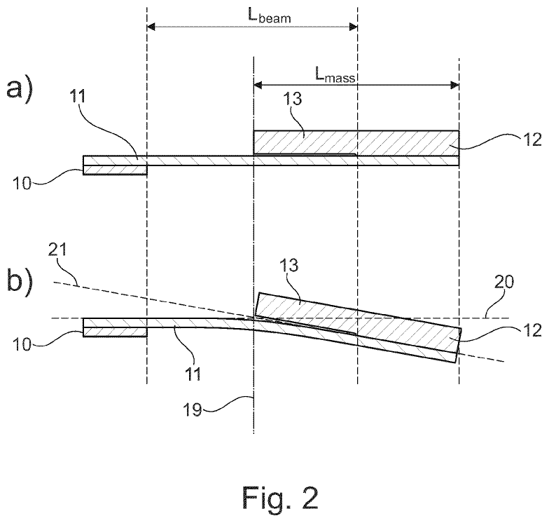

Turning now to FIG. 2a a straight, i.e. unbended, cantilever beam 11 with a moveable mass 12, 13 secured thereto is depicted. It should be noted that only the right-hand side 12 of the moveable mass, cf. FIG. 2, is secured to the cantilever beam 11. Thus, no adhesive is provided between the left-hand side 13 of the moveable mass and the cantilever beam 11. The cantilever beam 11 is secured to a spacer 10. When the vibration sensor is exposed to external vibrations the moveable mass 12, 13 is displaced and the cantilever beam 11 is bended as a result thereof, see FIG. 2b. where the dotted line indicates the unbended state of the cantilever beam 11, whereas the dotted line 21 indicates the bended state of the cantilever beam 11. As depicted in FIG. 2b the cantilever beam 11 bends at the virtual hinge line 19. The functioning of the cantilever beam 11 can be considered a virtual hinge with a rotational stiffness. The virtual hinge is located at the intersection of horizontal lines 20 and 21. This location is indicated with the virtual hinge line 19. Thus, in order to provide maximum effectiveness in response to external vibrations the entire moveable mass 12, 13 is preferably arranged to the right of the virtual hinge line 19.

Referring now again to FIG. 3, a top view of the embodiment shown in FIG. 1 is depicted. As seen in FIG. 3, the moveable mass 12, 13 comprises a first part 12 and the second part 13 where the width of the second part 13 of the moveable mass is smaller than the width of the first part 12 of the moveable mass. FIG. 3 further depicts that the first part 12 of the moveable mass is substantially aligned with the moveable end of the cantilever beam 11, and that the second part 13 of the moveable mass is substantially aligned with the virtual hinge line 19 of the cantilever beam 11. FIG. 3 also depicts how the second part 13 of the moveable mass is arranged between two piezo electric layers 14, 14′ secured to the cantilever beam 11 in a manner so that the two piezo electric layers 14, 14′ intersect the virtual hinge line 19 for maximum response. As discussed in relation to FIG. 1, respective electrodes 15, 15′ are arranged on the two piezo electric layers 14, 14′. The electrodes 15, 15′ are connected to the electrode 17 on the first PCB 1 via wire bonding 16, 16′. Electrical connection to the signal processor (not shown) is provided via the via 9. An air gap 22 surrounds at least part of the cantilever beam 11 so that at least its moveable end is allowed to move. Moreover, the first PCB 1 is visible as well.

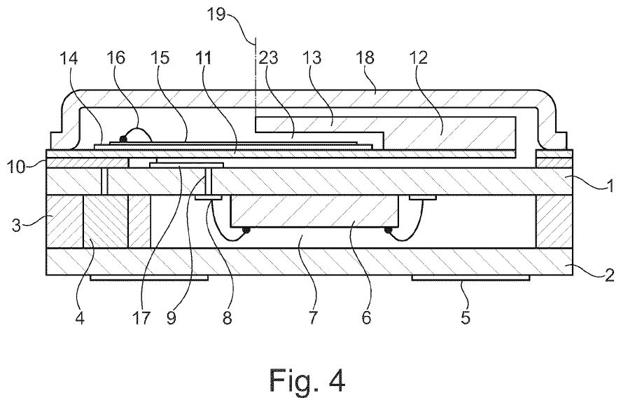

Turning now to FIG. 4, another embodiment of the vibration sensor is depicted. Similar to the embodiment depicted in FIG. 1, the embodiment depicted in FIG. 4 comprises a moveable mass comprising two parts 12, 13. Only a first part 12 of the moveable mass is secured to a suspension member 11, whereas the second part 13 of the moveable mass overhangs the suspension member 11, a piezo electric layer 14 and an electrode 15 secured thereto. The suspension member 11 has the form of a cantilever beam having 1) a static end secured to a spacer 10, and 2) a moveable end substantially aligned with the moveable mass part 12. The moveable mass 12, 13 and at least the moveable end of the cantilever beam 11 is adapted to displace when the vibration sensor is exposed to external vibrations. Again, a housing 18 protects the cantilever beam 11 and the moveable mass 12, 13 secured thereto.

As seen in FIG. 4, the second part 13 of the moveable mass overhangs the piezo electric layer 14 and an electrode 15 secured thereto so that an air gap 23 is formed below the second part 13 of the moveable mass. This spatial overlapping of the moveable mass (second part 13) and the piezo electric layer 14 and electrode 15 is advantageous in that it saves space.

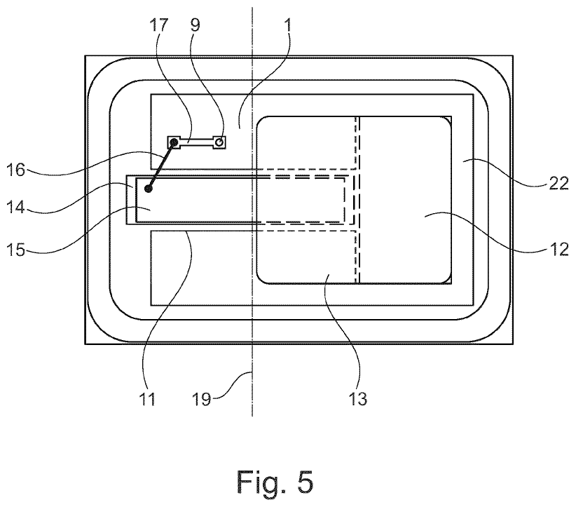

As already addressed, the vibration sensor applies a piezo electric detection principle for detecting the displacements of the moveable mass 12, 13 when the vibration sensor is exposed to external vibrations. In the embodiment shown in FIG. 4, see also top view in FIG. 5, a single piezo electric layer 14 with an electrode 15 arranged thereon are arranged on the cantilever beam 11 so that they intersect the virtual hinge line 19. As already mentioned a displacement (up or down) of the moveable mass 12, 13 bends the cantilever beam 11 at the virtual hinge line 19 whereby the piezo electric layer 14 is stretched or compressed in the lateral direction. The change in the lateral strain of the piezo electric layer 14 will induce a change in the electrical field strength across the piezo electric layer 14, i.e. across the thickness of the piezo electric layer 14. The change in the field strength across the piezo electric layer 14 will provide a change in the voltage generated between two electrodes arranged on opposite sides of the two piezo electric layer 14. In the embodiment shown in FIG. 1 the lower electrodes (grounded) of the piezo electric layer 14 is formed by the cantilever beam 11, whereas a separate electrode 15 is formed on the piezo electric layer 14. The separate electrode 15 is electrically connected to the signal processor 6 via the wire bonding 16, the electrode 17 on the first PCB 1, the via 9 through the first PCB 1 and the wire bonding 8 to the signal processor 6. Thus, the detected voltage change across the piezo electric layer 14 is processed by the signal processor 6 that may be operating in the analog or digital domain applying any digital coding scheme.

Similar to the embodiment depicted in FIG. 1 the vibration sensor depicted in FIG. 4 further comprises a second PCB 2 comprising first and second opposing surfaces, wherein one or more contact pads 5 are provided on the second surface of the second PCB 2. The one or more contact pads 5 facilitate easy connection of the vibration sensor to external electronic devices, such as external signal processors, filters, amplifiers etc. in for example hearing devices. Moreover, a spacer 3 is provided between the first PCB 1 and the second PCB 2 so that a cavity 7 is formed by the first PCB 1 and the second PCB 2 and the spacer 3. The spacer 3 comprises one or more vias 4 for electrically connecting the first PCB 1 and the second PCB 2.

Referring now to FIG. 5 a top view of the embodiment shown in FIG. 4 is depicted. As seen in FIG. 5 the moveable mass 12, 13 comprises a first part 12 and the second part 13 having the same width. However, and as already addressed, the second part 13 of the moveable mass is not secured to the cantilever beam 11. Instead, the second part 13 of the moveable mass overhangs the piezo electric layer 14 and the electrode 15 secured thereto, cf. the dotted lines in FIG. 5. FIG. 5 further depicts that the first part 12 of the moveable mass is substantially aligned with the moveable end of the cantilever beam 11, and that the second part 13 of the moveable mass, though it is overhanging the piezo electric layer 14 and the electrode 15, is substantially aligned with the virtual hinge line 19 of the cantilever beam 11. FIG. 5 also depicts how the piezo electric layer 14 intersects the virtual hinge line 19 for maximum response. As discussed in relation to FIG. 4 the electrode 15 is arranged on the piezo electric layers 14. The electrode 15 is electrically connected to the electrode 17 on the first PCB 1 via wire bonding 16. Electrical connection to the signal processor (not shown) is provided via the via 9. Similar to the top view depicted in FIG. 3 an air gap 22 surrounds at least part of the cantilever beam 11 so that at least its moveable end is allowed to move. Moreover, the first PCB 1 is visible as well.

Although the present invention has been discussed in the foregoing with reference to exemplary embodiments of the invention, the invention is not restricted to these particular embodiments which can be varied in many ways without departing from the invention. The discussed exemplary embodiments shall therefore not be used to construe the appended claims strictly in accordance therewith. On the contrary, the embodiments are merely intended to explain the wording of the appended claims, without intent to limit the claims to these exemplary embodiments. The scope of protection of the invention shall therefore be construed in accordance with the appended claims only, wherein a possible ambiguity in the wording of the claims shall be resolved using these exemplary embodiments.

1. A vibration sensor comprising
a) a carrier substrate comprising a first surface and a second surface,
b) a suspension member and a moveable mass secured thereto, wherein the moveable mass and/or at least part of the suspension member is/are adapted to vibrate when the vibration sensor is exposed to external vibrations,
c) a read-out arrangement for detecting vibrations of the moveable mass and/or at least part of the suspension member, and
d) a signal processor for at least processing an electric signal from the read-out arrangement,
wherein the read-out arrangement comprises one or more piezo electric layers and one or more electrodes arranged on the respective piezo electric layers,
wherein
the suspension member forms a cantilever beam comprising a static end, a moveable end and a virtual hinge line arranged in between, and in that at least part of the moveable mass is secured to the cantilever beam between the virtual hinge line and the moveable end, and in that the one or more piezo electric layers are secured to the cantilever beam in a manner so that the one or more piezo electric layers intersect the virtual hinge line.

2. A vibration sensor according to claim 1, wherein at least part of the moveable mass extends from the moveable end to the virtual hinge line of the cantilever beam.

3. A vibration sensor according to claim 1, wherein the moveable mass comprises a first part being substantially aligned with the moveable end of the cantilever beam, and a second part being substantially aligned with the virtual hinge line of the cantilever beam.

4. A vibration sensor according to claim 3, wherein the width of the second part of the moveable mass is smaller than the width of the first part of the moveable mass.

5. A vibration sensor according to claim 4, wherein at least part of the second part of the moveable mass is arranged between two piezo electric layers secured to the cantilever beam in a manner so that the two piezo electric layers intersect the virtual hinge line.

6. A vibration sensor according to claim 3, wherein the first part of the moveable mass is secured to the cantilever beam, and in that the second part of the moveable mass forms an overhang above the cantilever beam so that an air gap is formed between the second part of the moveable mass and the cantilever beam.

7. A vibration sensor according to claim 6, wherein one or more piezo electric layers are secured to the cantilever beam in a manner so that the one or more piezo electric layers extend into the air gap between the second part of the moveable mass and the cantilever beam, and intersect the virtual hinge.

8. A vibration sensor according to claim 1, wherein the moveable mass and the signal processor are arranged on opposite sides of the carrier substrate.

9. A vibration sensor according to claim 1, wherein the carrier substrate comprises a first PCB comprising first and second opposing surfaces.

10. A vibration sensor according to claim 9, wherein the signal processor is secured to the second surface of the first PCB.

11. A vibration sensor according to claim 9 wherein the vibration sensor further comprises a spacer secured to the second surface of the first PCB, and in that the spacer comprises one or more vias electrically connected to the second surface of the first PCB.

12. A vibration sensor according to claims 11, wherein the vibration sensor further comprises a second PCB comprising first and second opposing surfaces, and in that the one or more vias of the spacer are electrically connected to the first surface of the second PCB, and in that one or more contact pads are provided on the second surface of the second PCB for connecting the vibration sensor to external electronic devices.

13. A hearing device comprising a vibration sensor according to any of the claim 1, wherein the hearing device comprises a hearing aid, a hearable, a headset, an earbud or a similar device.

14. Use of a vibration sensor according to any of claim 1 in a hearing device, wherein the vibration sensor is used for detecting voice induced vibrations in the skull of the user of the hearing device, and in that the detected voice induced vibrations are used for voice recognition of the user's own voice.
